(19) United States
(12) Patent Application Publication
(10) Pub. No.: US 2011/0018065 A1
(43) Pub. Date: Jan. 27, 2011

(54) METHOD FOR MANUFACTURING SEMICONDUCTOR DEVICE AND SEMICONDUCTOR DEVICE

(75) Inventors: Gilberto Curatola, Korbek-Lo (BE); Prabhat Agarwal, Brussels (BE); Mark J. H. Van Dal, Heverlee (BE); Vijayaraghavan Madakasira, Louvain (BE)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/918,398

(22) PCT Filed: Feb. 17, 2009
(86) PCT No.: PCT/IB2009/050641

§ 371 Date: Aug. 19, 2010

(30) Foreign Application Priority Data
Feb. 26, 2008 (EP) 08102004.2

(51) Int. Cl. H01L 29/775; H01L 27/088; H01L 21/336

(52) U.S. Cl. 257/368; 257/288; 438/284; 257/E29.245

(57) ABSTRACT

A method of manufacturing a semiconductor device is disclosed comprising providing an insulating carrier (10) such as an oxide wafer; providing a channel structure (20) between a source structure (12) and a drain structure (14) on said carrier (10); selectively removing a part of the channel structure (20), thereby forming a recess (22) between the channel structure (20) and the carrier (10); exposing the device to an annealing step such that the channel structure (20′) obtains a substantially cylindrical shape; forming a confinement layer (40) surrounding the substantially cylindrical channel structure (20′); growing an oxide layer (50) surrounding the confinement layer (40); and forming a gate structure (60) surrounding the oxide layer (50). The substantially cylindrical channel structure 20′ may comprise the semiconductor layer 30. A corresponding semiconductor device is also disclosed.

The present invention relates to a method for manufacturing a semiconductor device, and in particular a gate-all-around (GAA) FinFET device.

The present invention further relates to a semiconductor device and in particular a GAA FinFET device.

The continuous scaling of the dimensions of a conventional bulk metal oxide semiconductor field effect transistor (MOSFET) is becoming increasingly difficult due to the uncontrollable short channel effects. Such effects cause a large degradation in the transistor performance, in its switching efficiency as well as in its speed during commutations. For this reason, several alternative transistor designs are being investigated, such as the use of new materials such as high-k dielectric and metal gate materials in conventional transistor designs, and/or the development of alternative transistor architectures.

A particular architecture that has attracted a lot of attention is the so-called FinFET device, in which a thin fin-shaped channel is provided between a source and drain region on an insulating carrier such as an oxide wafer, with multiple gates controlling the channel conductivity. FinFET devices are considered to be promising due to their excellent intrinsic performance and their high compatibility with the conventional CMOS process, which means that these devices can be manufactured without the need for large investments in new manufacturing equipment.

One of the key features of FinFET devices is represented by a very high electrostatic integrity compared to conventional transistor architectures. This is due to the additional control over the carriers in the channel exerted by the multi-gate configuration. The presence of two or three gate thus provides a much better control of short channel effects, resulting in high performances and improved scalability compared to conventional transistor designs. A natural extension of a FinFET device is represented by the gate-all-around (GAA) device, in which a gate structure envelopes the fin-shaped channel. This further improves control over short channel effects. An example of such a device is disclosed in U.S. patent application No. U.S. 2007/0145431.

The downscaling of transistor dimensions has further initiated interest in designing devices that exhibit quantization effects, such as transistors based on quantum wires. U.S. patent application No. 2008/0014689 discloses a gate-all-around planar nanowire semiconductor device, in which the planar nanowires are formed between a source and a drain over an insulating layer of a semiconductor substrate, with a gate stack being grown all-around the planar nanowires. The gate stack is subsequently etched and patterned. During this process, the planar nanowires are severed between the gate and the source, and between the gate and the drain, leaving portions of the gate-all-around planar nanowires remain between the source and the drain and serve as the active region of the channel. The remaining gate-all-around planar nanowires are epitaxially regrown to reconnect to the source and the drain.

This device has several drawbacks. The manufacturing process is relatively complex, and results in a semiconductor nanowire having a planar shape, rather than a cylindrical shape facilitating optimization of the quantization effects.

The present invention seeks to provide a method of manufacturing a semiconductor device having a cylindrically shaped channel with a surrounding gate.

The present invention further seeks to provide a semiconductor device having a cylindrically shaped channel with a surrounding gate.

According to a first aspect of the present invention, there is provided a method of manufacturing a semiconductor device, comprising providing an insulating carrier; providing a channel structure between a source structure and a drain structure on said carrier; selectively removing a part of the channel structure, thereby forming a recess between the channel and the carrier; exposing the device to an annealing step such that the channel structure obtains a substantially cylindrical shape; forming a confinement layer surrounding the substantially cylindrical channel structure; growing an oxide layer surrounding the confinement layer; and forming a gate structure surrounding the oxide layer.

The method of the present invention allows for the formation of a cylindrical channel structure using conventional CMOS processing steps. For instance, the combined channel, source and drain structures may be a FinFET structure. The confinement layer, i.e. layer having a larger band gap than the semiconductor layer of the quantum wire, ensures that charge carriers are confined in the cylindrical channel structure, thus creating a quantum wire.

In an embodiment, the method further comprises growing a semiconducting layer surrounding the substantially cylindrical channel structure prior to forming the confinement layer, and wherein the confinement layer surrounds the substantially cylindrical channel structure and the semiconducting layer, the substantially cylindrical channel acting as a further confinement layer for the semiconducting layer. This creates a quantum well structure in between an inner and an outer confinement structure. This further improves the efficiency of the quantum confinement, and thus aids in reducing the occurrence of charge carriers at the surface of the wire. The semiconducting layer may be grown epitaxially.

The channel structure formed on the insulating carrier has a square cross section. This has the advantage over e.g. a conventional FinFET process that the channel structure may be more easily formed, thus reducing process complexity. Moreover, it has been found that the use of a channel structure having a square cross section yields a device having improved characteristics compared to devices formed in a conventional FinFET process.

The above method may be used to form both nMOS and pMOS type devices, thus facilitating the manufacture of integrated circuits (ICs) comprising the inventive semiconductor devices through conventional CMOS processes.

In an embodiment, the channel structure is a silicon channel structure, and the step of forming a confinement layer comprises growing a silicon/germanium (SiGe) layer surrounding the substantially cylindrical channel structure; and growing the oxide layer surrounding the SiGe layer at a predefined temperature, said predefined temperature facilitating the migration of Ge atoms from the SiGe layer towards the substantially cylindrical channel structure, thereby converting the SiGe layer into the confinement layer. This embodiment yields a p-type quantum well for transporting holes between the source and drain regions.

The complementary n-type device may be achieved by an embodiment wherein the channel is a strained silicon channel structure, and wherein forming the confinement layer comprises epitaxially growing a SiGe layer. Instead of strained silicon, suitable group III-V materials may be used for the semiconductor quantum well of the n-type device.

A p-type device having a quantum well sandwiched between two confinement structures may be achieved when the channel structure is a silicon channel structure, wherein growing a semiconducting layer comprises epitaxially growing a SiGe layer; and forming the confinement layer comprises epitaxially growing a silicon layer surrounding the SiGe layer. Such a device has a two-layer core structure, comprising an inner confinement silicon structure enveloped by a SiGe semiconductor quantum well.

The corresponding n-type device may be formed when the channel structure is a SiGe channel structure, wherein growing a semiconducting layer comprises growing a strained silicon layer; and forming the confinement layer comprises epitaxially growing a SiGe layer surrounding the strained silicon layer.

According to another aspect of the present invention, there is provided a semiconductor device on an insulating carrier, the device comprising a source region, a drain region, and a channel structure between the source region and the drain region, the channel structure comprising a substantially cylindrical core structure comprising a semiconducting material; a confinement layer surrounding the core structure; an oxide layer surrounding the confinement layer; and a gate structure surrounding the oxide layer. Such a device, which is manufactured by the method of the present invention, has excellent conductive properties and a controllable short channel effects, and can be manufactured using conventional CMOS process techniques.

In an embodiment, the core structure comprises a further confinement structure surrounded by a layer of the semiconducting material, thus achieving a quantum well sandwiched between two confinement structures. The semiconducting material of these semiconductor devices may be silicon/germanium and the confinement structure(s) may comprise silicon in case of p-type devices. The semiconducting material may be strained silicon and the confinement structure(s) may comprise silicon/germanium in case of n-type devices. Alternatively, the n-type devices may comprise a suitable group III-V material as semiconductor material.

Embodiments of the invention are described in more detail and by way of non-limiting examples with reference to the accompanying drawings, wherein

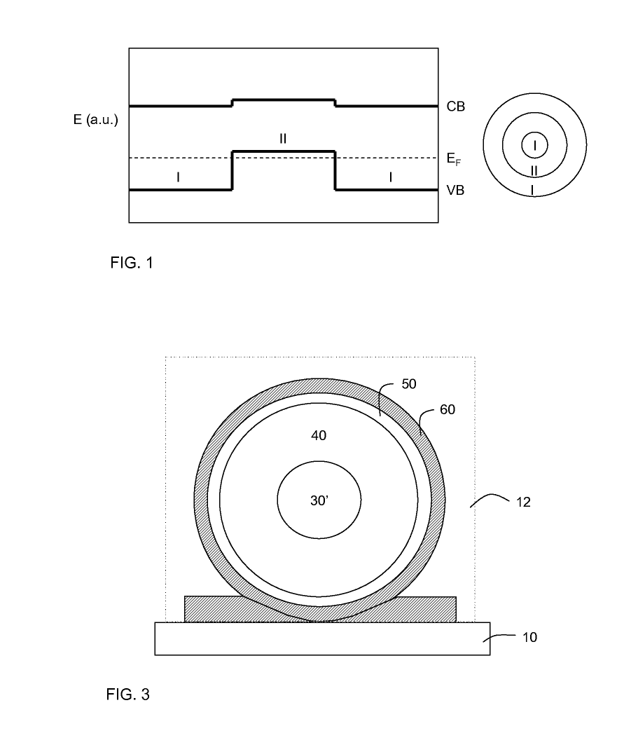

FIG. 1 schematically depicts the principle of a quantum well device;

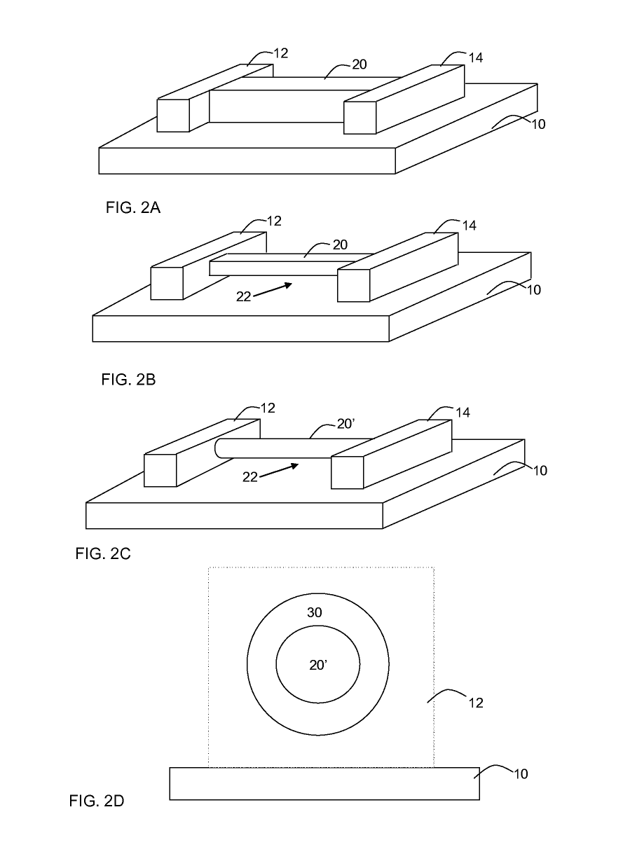

FIGS. 2A-F schematically depict key steps of an embodiment of a method of manufacturing a semiconductor device in accordance with an embodiment of the present invention; and

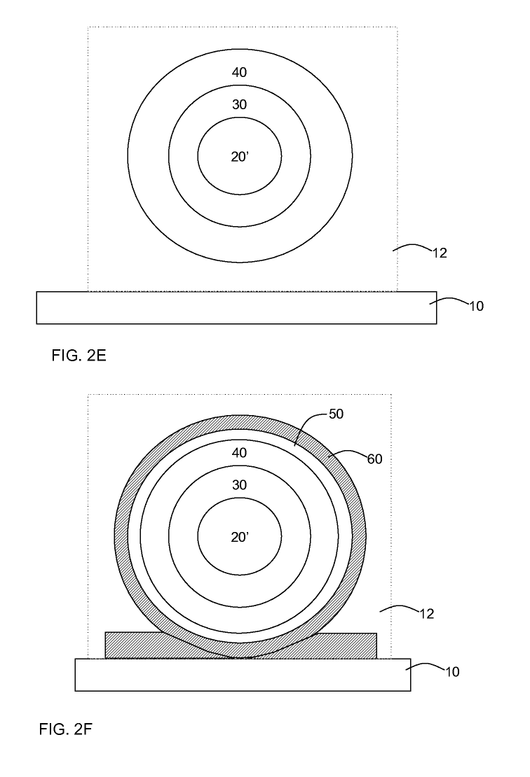

FIG. 3 schematically depicts a semiconductor device manufactured in accordance with an alternative embodiment of the present invention.

It should be understood that the Figures are merely schematic and are not drawn to scale. It should also be understood that the same reference numerals are used throughout the Figures to indicate the same or similar parts.

FIG. 1 schematically depicts the concept of a cylindrical quantum well. Such wells are sometimes also referred to as quantum wires. In this particular case, an inner region II, e.g. a Ge cylindrical channel, is sandwiched between two regions I, e.g. an inner and an outer silicon layer. The region II is used as a charge transport layer, e.g. a holes transport layer. A quantum well is formed in region II due to the difference in energy gaps between the valence band (VB) and the conduction band (CB) splitting for regions I and region II respectively. As a result, charge carriers, e.g. holes, are confined inside the quantum well. In other words, regions I act as confinement layers to confine the charge carriers to region II. The large sub-band splitting observed in the quantum well, wherein the valence band level may be raised to above the Fermi level (E_{F}), largely reduces intra-sub-band scattering events. Consequently, the carrier mobility and the current drive capability of the device is increased. In case of region II comprising Ge or SiGe and regions I comprising Si, a pMOS device may be obtained. An nMOS device may be achieved by sandwiching a strained Si layer between two SiGe layers. Alternatives to strained Si include suitable group III-V materials, or combinations thereof.

One of the advantages of such a cylindrical quantum well structure is the potential to achieve ballistic transport behavior. Such behavior has already been demonstrated for Ge/Si nanowires by Jie Xiang at al. in Nature, pp. 489-493 (2005). A drawback of this device is that its manufacturing cannot be achieved with conventional CMOS processes, but requires a highly experimental technology based on growing nanowires instead.

A further advantage is that the lack of dopants in the channel and the large sub-band splitting obtained as a consequence of the two-dimensional quantum confinement allow for a substantial increase of the mean free path in the device. A mean free path larger than 500 nm has been already experimentally demonstrated in the aforementioned publication by Jie Xiang at al. Even in case the transport of charge carriers through region II is collision dominated, the device performance is improved by the high charge carrier mobility at low and high field. Indeed, as a consequence of the large sub-band splitting, the inter-sub-band scattering is largely reduced. Therefore, few sub-bands participate effectively to the transport and hence high mobility is expected.

Such a device is further characterized by a higher immunity to surface states with respect to planar equivalent such as disclosed in U.S. patent application No. 2008/0014689. The cylindrical nature of the transistor and the radial quantum confinement induce a conducting channel in the centre of the cylinder, i.e. far away from the cylinder surface. This greatly reduces the occurrence of scattering events due to collisions with impurities at the surface, thus greatly improving the device mobility. The reduced diameter of the conducting channel, e.g. a SiGe channel, as well as of the confinement layer, e.g. a Si cap layer, allow for an increase in the Ge concentration in region II without introducing strain in the device.

FIGS. 2A-F schematically depict a method of manufacturing such a device using CMOS compatible processing techniques. In FIG. 2A, a insulating carrier 10 such as an oxide wafer is provided, onto which a silicon layer is formed and patterned into a source structure 12, a drain structure 14 and a channel structure 20 wedged between the source structure 12 and the drain structure 14. Source structure 12, drain structure 14 and channel structure 20 may be formed using a conventional FinFET process, with channel structure 20 being the ‘fin’ of the FinFET.

Many suitable CMOS compatible processes for manufacturing such a FinFET structure are well-known to the skilled person, and are therefore not further explained for reasons of brevity only. It is however emphasized that in contrast to the conventional FinFET manufacturing processes, the high aspect-ratio which characterizes conventional FinFET devices is not necessary for the semiconductor device of the present invention. In fact, the fin preferably has a square cross-section since this simplifies the etching process yielding the fin, and improves the quality of the patterned fin.

In FIG. 2B, a recess 22 formed between the Si channel structure 20 and the insulating carrier 10. Such a recess 22 may be formed by any suitable etching step. For instance, the oxide carrier 10 may be underetched. Alternatively, the channel structure 20 may comprise a Si/SiGe stack, with the SiGe layer being selectively removed, e.g. by means of a wet etch. Such etching steps are all well known, see for instance E. Saarniletho et al. in ‘Local buried oxide technology for HV transistors integrated in CMOS’, in the proceedings of 19th International Symposium on Power Semiconductor Devices and IC's, 2007. ISPSD '07, 27-31 May 2007, page(s) 81-84, and will therefore not be explained any further.

In FIG. 2C, the recessed channel structure is converted into a substantially cylindrical channel structure 20′. This may be achieved by any suitable process step, such as a hydrogen annealing step disclosed by Fu-Liang Yang et al., in VLSI, pp. 196-197 (2004), in which such an annealing step was successfully used to form wires having a substantially cylindrical shape.

In FIG. 2D, which depicts the cross section of channel structure 20′ as seen through source region 12, a semiconducting layer 30 is grown over the substantially cylindrical channel structure 20′. For example, the semiconducting layer 30 may comprise a Si₍₁₋ₓ₎Geₓ layer, preferably with 0<<x<1. A relatively high Ge content in this layer is preferred to enhance the quantum well behavior of this layer. Preferably, x is in the area of 0.3-0.4. It has been found that this range allows for the enhancement the band gap splitting between the semiconducting layer 30 and the surrounding confinement layer(s) without introducing strain into the semiconductor device. It has been found that the cylindrical shape of this layer allows for a higher Ge content in this layer without introduction of strain than compared to prior art solutions in which planar SiGe layers are used, where the maximum fraction of Ge was typically limited to x=0.2.

The Si₍₁₋ₓ₎Geₓ layer may be formed by an epitaxial growth step. The epitaxial growing of such layers is well known to the skilled person, and will not be further explained for reasons of brevity only.

The semiconducting layer 30 should preferably not exceed a thickness of 10 nm in order to obtain pronounced quantum confinement effects in this layer.

In FIG. 2E, a confinement layer 40 such as a silicon cap layer is grown around the semiconductor layer 30. The confinement layer may be grown in any suitable way, e.g. by means of an epitaxial growth step. Preferably, the thickness of this cap layer should be only a few nanometers thick, e.g. 2-3 nm, to allow the growth of a high quality oxide layer over this cap layer, and to avoid the formation of parasitic conductive channels.

In FIG. 2F, the quantum well structure is completed by the formation of a conventional all-around gate stack including an oxide layer 50 and the gate layer 60. The oxide layer 50 may comprise any suitable material, e.g. a SiO₂ based oxide or a material having a dielectric constant in excess of five, i.e. a high-k dielectric. The gate layer 60 may comprise any suitable material, e.g. polySi or a metal gate electrode. The semiconductor device may be completed in any suitable way. For instance, source and drain region formation may proceed in a manner similar to the manufacturing of conventional bulk MOSFETs.

In case of the cylindrical channel structure 20′ comprising Si, the semiconductor layer 30 comprising Si₍₁₋ₓ₎Geₓ and the confinement layer 40 comprising Si, a pMOS-type quantum well device is achieved, wherein the cylindrical channel structure 20′ acts as a further confinement structure for the Si₍₁₋ₓ₎Geₓ quantum well.

The corresponding nMOS-type device may be formed by altering the above process as follows. A SiGe channel structure 20′ may be formed, followed by growing a strained Si semiconductor layer 30 surrounding the SiGe channel structure 20′. The strained Si semiconductor layer 30 may be covered by a SiGe confinement layer 40, which may be grown epitaxially or in any other suitable way.

FIG. 3 shows an alternative embodiment of a semiconductor device of the present invention, wherein the inner confinement layer has been omitted. Hence, the semiconductor layer 30 is the innermost structure of the quantum well semiconductor device according to this embodiment of the present invention.

A pMOS-type device as shown in FIG. 3 may be formed by amending the process steps in FIGS. 2A-F as follows. Following the deposition of the Si₍₁₋ₓ₎Geₓ semiconductor layer 30 over the cylindrical Si channel structure 20′, the step of depositing the confinement layer 40 is omitted, and the method proceeds to growing the oxide layer 50 over the Si₍₁₋ₓ₎Geₓ semiconductor layer 30. The intermediate device is exposed to a thermal budget, which may be during or following the oxidation step, which forces the migration of the Ge atoms from the semiconductor layer 30 towards the substantially cylindrical Si channel structure 20′, thereby converting layer 20′ into a semiconductor layer 30′, and converting original semiconductor layer 30 into a confinement layer 40. The semiconductor layer 30′ typically will comprise a higher concentration of Ge atoms than the confinement layer 40. It is emphasized that in this way, a semiconductor layer 30′ having high Ge concentrations can be achieved without introducing strain and defects in the semiconductor device.

The corresponding nMOS-type device may be obtained by using the substantially cylindrical Si channel structure 20′ as the semiconductor layer, and the Si₍₁₋ₓ₎Geₓ layer 30 as the confinement structure, in which case the deposition of the confinement layer 40 may be omitted from the process depicted in FIGS. 2A-F. For such an nMOS-type device, it is preferable to limit the Ge concentration in the Si₍₁₋ₓ₎Geₓ layer, e.g. x≦0.2, to ensure that a high quality gate stack may be formed over this layer. The band gap misalignment in this device is given by the energy gap difference between the Si channel and the SiGe confinement layer. The energy gap of pure Ge is roughly half of the energy gap of silicon and, as a crude approximation, the energy gap of a Si₍₁₋ₓ₎Ge₍ₓ₎ layer may be obtained as a linear interpolation between the absolute band gap values for pure Si (i.e. x=1) and pure Ge (i.e. x=0) for the considered x mole fraction. It will be appreciated that to ensure that a sufficient band gap misalignment between the Si semiconducting channel 30 and the SiGe confinement layer 40 remains, x should be substantially larger than 0, e.g. 0.1×0.2 for this embodiment.

The aforementioned quantum well manufacturing processes have the advantage that they can be implemented using CMOS compatible process steps, and that the process steps are all scalable, such that future submicron devices, e.g. devices having feature sizes well below the 22 nm technology feature sizes, may also be achieved using these processes.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The invention can be implemented by means of hardware comprising several distinct elements. In the device claim enumerating several means, several of these means can be embodied by one and the same item of hardware. The mere fact that certain measures are recited in mutually different dependent claims does not indicate that a combination of these measures cannot be used to advantage.

1. A method of manufacturing a semiconductor device, comprising:
providing an insulating carrier;
providing a channel structure between a source structure and a drain structure on said carrier;
selectively removing a part of the channel structure, thereby forming a recess between the channel structure and the carrier;
annealing the device such that the channel structure obtains a substantially cylindrical shape;
forming a confinement layer surrounding the substantially cylindrical channel structure;
growing an oxide layer surrounding the confinement layer; and
forming a gate structure surrounding the oxide layer.

2. A method as claimed in claim 1, further comprising growing a semiconducting layer surrounding the substantially cylindrical channel structure prior to forming the confinement layer, and wherein the confinement layer surrounds the substantially cylindrical channel structure and the semiconducting layer, the substantially cylindrical channel structure acting as a further confinement layer for the semiconducting layer.

3. A method as claimed in claim 2, wherein the semiconducting layer is grown epitaxially.

4. A method as claimed in claim 1, wherein the channel structure has a square cross section.

5. A method as claimed in claim 1, wherein the annealing step comprises a hydrogen annealing.

6. A method as claimed in claim 1, wherein the channel structure is a silicon channel structure, and wherein of forming a confinement layer comprises:
growing a silicon/germanium (SiGe) layer surrounding the substantially cylindrical channel structure; and
growing the oxide layer surrounding the SiGe layer at a predefined temperature, said predefined temperature facilitating the migration of Ge atoms from the SiGe layer towards the substantially cylindrical channel structure, thereby converting the SiGe layer into the confinement layer.

7. A method as claimed in claim 1, wherein the channel structure is a strained silicon channel structure, and wherein forming the confinement layer comprises epitaxially growing a SiGe layer.

8. A method as claimed in claim 2, wherein:
the channel structure is a silicon channel structure; and
growing a semiconducting layer further comprises epitaxially growing a SiGe layer; and
forming the confinement layer further comprises epitaxially growing a silicon layer surrounding the SiGe layer.

9. A method as claimed in claim 2, wherein:
the channel structure is a SiGe channel structure;
growing a semiconducting layer further comprises growing a strained silicon layer; and
forming the confinement layer further comprises epitaxially growing a SiGe layer surrounding the strained silicon layer.

10. A semiconductor device on an insulating carrier, the device comprising a source region, a drain region, and a channel structure between the source region and the drain region, the channel structure comprising:
a substiantially cylindrical core structure comprising a semiconducting material;
a confinement layer surrounding the core structure;
an oxide layer surrounding the confinement layer; and
a gate structure surrounding the oxide layer.

11. A semiconductor device as claimed in claim 10, wherein the core structure comprises a further confinement structure surrounded by a layer of the semiconducting material.

12. A semiconductor device as claimed in claim 10, wherein the semiconducting material is silicon/germanium and the confinement structure(s) comprises silicon.

13. A semiconductor device as claimed in claim 10, wherein the semiconducting material is strained silicon and the confinement structure(s) comprises silicon/germanium.

14. An integrated circuit comprising a plurality of semiconductor devices as claimed in claim 10.
